(19) United States
(12) Patent Application Publication
(10) Pub. No.: US 2012/0097971 A1
(43) Pub. Date: Apr. 26, 2012

(54) CONTIGUOUS AND VIRTUALLY CONTIGUOUS AREA EXPANSION OF SEMICONDUCTOR SUBSTRATES

(76) Inventor: Scott L. Jacobs, Pittsboro, NC (US)

(21) Appl. No.: 13/281,356

(22) Filed: Oct. 25, 2011

Related U.S. Application Data
(60) Provisional application No. 61/406,521, filed on Oct. 25, 2010.

(51) Int. Cl. H01L 29/20; H01L 21/306; H01L 29/06

(52) U.S. Cl. 257/76; 257/618; 438/689; 257/E29.022; 257/E29.089; 257/E21.215

(57) ABSTRACT

Substrates are processed, with a high degree of topography, to produce a variety of semiconductors or other devices and are then stretched out, substantially flat, to achieve a significant increase in surface area. Devices made from a contiguous structure of a single, active crystalline material or from non-contiguous structures of multiple materials, such as a combination of dielectrics, thin film metals and active crystalline semiconductors, are fabricated by utilizing anisotropically etched, high aspect ratio configurations of the active material. The structure is then stretched out to achieve a significant increase in surface area, thereby enabling a substantial reduction in the cost of the substrate materials per unit area in the final product.

### CROSS-REFERENCE TO RELATED APPLICATION(S)

This application claims priority to and the benefit of U.S. Provisional Patent Application No. 61/406,521, entitled “ACCORDION PROCESS CONFIGURATION AND THIN FILM ARTIFICIAL INTEGRATION FOR SURFACE AREA MAGNIFICATION OF SEMICONDUCTOR SUBSTRATES,” filed in the U.S. Patent and Trademark Office on Oct. 25, 2010, the entire content of which is herein incorporated by reference.

### BACKGROUND

1. Field

Aspects of embodiments of the present invention relate to area expansion of semiconductor substrates.

2. Description of the Related Art

There is yet a need to lower the cost of producing light emitting diode (LED) and other semiconductor devices such as photovoltaic solar cells that may benefit from the expansion or magnification of substrate surface area.

### SUMMARY

Various embodiments of the invention disclosed herein engender opportunities to address this and other needs by 1) significantly reducing the use of raw materials, 2) concentrating costly process steps, and 3) allowing for processes for large-scale LED and photovoltaic products and other applications to be performed on lower cost equipment with smaller footprints in smaller factories.

Aspects of embodiments of the present invention are directed toward contiguous and virtually contiguous area expansion of semiconductor substrates, with applications to such areas as light emitting diode and photovoltaic devices, photolithography, thin film multi-chip modules (MCMs). “Virtually contiguous” is meant to convey that even if the semiconductor substrate is not purely contiguous from a strict technical standpoint, it is contiguous from a practical standpoint, or at least contiguous for most intents and purposes. Further aspects are directed toward the packaging of micro- and nanoelectronic devices with applications in fields such as lighting, solar energy, biochips and opto-electronics.

Chips are defined by the electronics industry as smaller pieces of semiconductors cut out from a processed wafer of semiconductor material. Individual chips are traditionally passivated by encapsulation prior to integrating a plurality of them into a larger electronic system, usually on a printed circuit board. The encapsulation and integration steps are collectively known as “packaging” in the industry. MCM technology is typically defined by the electronics industry as a plurality of interconnected but unencapsulated semiconductor chips. Several subclasses of MCMs exist, including MCM-D, where “D” refers to interconnects formed by thin-film deposition. Well-understood MCM-D techniques may be utilized to achieve area expansion by pre-patterning semiconductor wafers with thin films that serve as both etch masks and connecting hinges that physically hold and electrically connect a plurality of chips together.

Embodiments of the present invention provide for a low cost means of expanding, amplifying or magnifying the area of a process substrate by cutting out a plurality of smaller chips from a wafer and changing the active device face of the semiconductor material from the original wafer face to a substantially orthogonal face etched into the wafer that defines the chips. This area expansion takes place without the need to utilize pick-and-place techniques in order to substantially lower the cost per unit area of semiconductor devices such as light emitting diodes and photovoltaic solar cells.

Further embodiments of the present invention enable process concentration over smaller footprints. For example, common semiconductor processes such as diffusion or metal organic chemical vapor deposition (MOCVD) are usually performed over planar surfaces whereas according to embodiments of the present invention, these and other similar processes can be performed over the unstretched, concentrated substrate, yielding a much larger area of processed substrate.

Still further embodiments of the present invention provide for fine-scale, high quality, high reliability and low cost thin film electrical contacts and interconnections that may be fabricated without the need for manual or automatic, wire-by-wire electrical interconnect operations and gross-scale hardware to achieve the same.

Still further embodiments of the present invention provide for a final configuration of products that is conducive to the stacking of devices to achieve greater complexity of the final product (e.g. three-color flat panel displays formed by stacking thin film LED sheets).

Still further embodiments of the present invention provide for a final configuration that is inherently flexible so that in a free-standing configuration the final product, 1) on a gross scale, may be bent to a significant degree without damage (e.g. wearable LED or photovoltaic cloth or fabric, rolls of photovoltaic material, etc.) and 2) on a fine scale, may be capable of supporting micro-electrical-mechanical systems (MEMS) devices for applications such as electronically induced motion for solar tracking or concentration.

According to an exemplary embodiment of the present invention, a contiguous thin film/semiconductor composite structure for semiconductor devices is provided. The structure has a shape that substantially resembles bellows of an accordion. Upon completion of etch resistant thin film patterning on top and bottom faces of a semiconductor substrate, and semiconductor etch processes that formed said structure, the structure may be pulled or stretched out to a configuration with substantially planar surface area to achieve a significantly larger surface area than the semiconductor substrate.

The structure may further include a deep etch of a crystalline wafer of a particular faced plane of crystalline gallium nitride (GaN) or other semiconducting crystals to reveal facets of other crystal planes or random planes to produce non-polar or semi-polar faced crystal substrates from an original polar faced substrate.

At least one light emitting diode (LED) may be made from the structure.

At least one light emitting diode (LED) may be made from the previous structure.

At least one photovoltaic device may be made from the previous structure.

According to another exemplary embodiment of the present invention, a contiguous thin film/semiconductor composite structure for semiconductor devices is provided. The structure has a shape that substantially resembles a serpentine. Upon completion of etch resistant thin film patterning upon one or more edges of a semiconductor substrate, and semiconductor etch processes that formed said structure, the structure may be pulled or stretched out to achieve a substantially linear shape having a significantly larger surface area than the semiconductor substrate.

The structure may further include a deep etch of a crystalline wafer of a particular faced plane of crystalline gallium nitride (GaN) or other semiconducting crystals to reveal facets of other crystal planes or random planes to produce non-polar or semi-polar faced crystal substrates from a polar faced substrate.

At least one light emitting diode (LED) may be made from the structure.

At least one light emitting diode (LED) may be made from the previous structure.

At least one photovoltaic device may be made from the previous structure.

According to yet another exemplary embodiment of the present invention, a contiguous coil of semiconductor material is provided. The coil is patterned in a substantially spiral shape with etch resistant thin film masking materials, and etched into the substantially spiral-shaped coil configured to be held at one end and pulled out at another end to achieve a substantially long and linear semiconductor substrate having a significantly larger planar surface area than the coil.

At least one light emitting diode (LED) may be made from the semiconductor substrate.

At least one photovoltaic device may be made from the semiconductor substrate.

According to still yet another exemplary embodiment of the present invention, a method is provided. The method includes: forming a semiconductor substrate substantially in an accordion shape; etch resistant thin film patterning on top and bottom faces of the semiconductor substrate; semiconductor etch processing the semiconductor substrate to form a contiguous thin film/semiconductor composite structure for semiconductor devices; and pulling or stretching out the composite structure to a configuration with a substantially planar surface area to realize a significantly larger planar footprint than that of the semiconductor substrate.

The method may further include deep etching of a crystalline wafer of a particular faced plane of crystalline gallium nitride (GaN) or other semiconducting crystals to reveal facets of other crystal planes or random planes to produce non-polar or semi-polar faced crystal substrates from an original polar faced substrate.

The method may further include forming at least one light emitting diode (LED) from the composite structure.

The method may further include forming at least one photovoltaic device from the composite structure.

According to still yet another exemplary embodiment of the present invention, a method is provided. The method includes: forming a semiconductor substrate substantially in a serpentine shape; etch resistant thin film patterning on one or more edges of the semiconductor substrate; semiconductor etch processing the semiconductor substrate to form a contiguous thin film/semiconductor composite structure for semiconductor devices; and pulling or stretching out the composite structure to achieve a configuration with a substantially linear shape and having a significantly larger planar footprint than that of the semiconductor substrate.

The method may further include deep etching of a crystalline wafer of a particular faced plane of crystalline gallium nitride (GaN) or other semiconducting crystals to reveal facets of other crystal planes or random planes to produce non-polar or semi-polar faced crystal substrates from a polar faced substrate.

The method may further include forming at least one light emitting diode (LED) from the composite structure.

The method may further include forming at least one photovoltaic device from the composite structure.

According to still yet another exemplary embodiment of the present invention, a method is provided. The method includes: patterning and etching semiconductor material using etch resistant thin film masking materials to form a substantially spiral shaped contiguous coil of the semiconductor material; holding the coil at one end; and pulling out the coil at another end to realize a substantially long and linear semiconductor substrate having a significantly larger planar surface area than the coil.

The method may further include forming at least one light emitting diode (LED) from the semiconductor substrate.

The method may further include forming at least one photovoltaic device from the semiconductor substrate.

These and other objectives can be provided for by stretching, unfolding or unrolling a smaller, thicker finished process substrate to achieve a substantially larger, or longer, thinner product according to embodiments of the present invention.

### BRIEF DESCRIPTION OF THE DRAWINGS

The accompanying drawings illustrate embodiments of the present invention, and together with the description, serve to explain the principles of the present invention.

FIG. 1 is a cross sectional view illustrating an example of a thin film embodiment of the present invention prior to release and expansion.

FIG. 2(A) is a cross sectional view illustrating fins, hinges, and a surface of devices prior to expansion according to an embodiment of the present invention. FIG. 2(B) illustrates the embodiment of FIG. 2(B) after expansion.

FIG. 3 illustrates a serpentine edge-connected vertical sidewall accordion structure according to an embodiment of the present invention.

### DETAILED DESCRIPTION

The illustrative embodiments that follow are only exemplary applications of the present invention and not intended to limit the scope of the invention.

According to exemplary embodiments of the present invention, substrates are processed, with a high degree of topography, to produce a variety of semiconductors or other devices and are then stretched out, substantially flat, to achieve a significant increase in surface area. Devices made from a contiguous structure of a single, active crystalline material or from non-contiguous structures of multiple materials, such as a combination of dielectrics, thin film metals and active crystalline semiconductors, are fabricated by utilizing anisotropically etched, high aspect ratio configurations of the active material. The structure is then stretched out to achieve a significant increase in surface area.

In exemplary embodiments, thin film interconnect structures and methods are used with either a contiguous ribbon or chips or fins of semiconductor substrates to enable both a substantially one-dimensional ribbon of active crystalline material or multi-chip modules (MCMs) of light emitting diodes (LED) devices or other electronic devices. Thin film MCMs of photovoltaic chips enable high voltage output with high reliability, low resistance contacts and wiring. MCMs of long thin fins of materials are produced without the need to pick-and-place individual fins by 1) first applying the thin film in specific configurations on the future top edges of the fins on a wafer face or the edges of a wafer prior to etching a wafer or other process substrate and 2) subsequently stretching the fins out in an accordion fashion to achieve a substantially flat substrate, or in the case of wafer edge side contacts or a spirally-etched wafer, to achieve a long, linear substrate to significantly increase the surface area of the material of the process substrate.

This enables a substantial reduction in the cost of the substrate materials per unit area in the final product.

An exemplary embodiment of the invention is as follows:

The cause of a serious deficiency in LED technology is known as droop wherein efficiency drops at increased power. The cause is not completely understood but is suspected by some to be due to Auger or non-radiative recombination. Assertions have been made that this droop may be minimized by producing LEDs on non-polar or semi-polar crystal planes. Gallium nitride (GaN) is the material of choice in the LED industry for manufacturing short wavelength (e.g. blue light emitting) LEDs. To date, GaN LEDs have been widely produced as deposited thin films of GaN on foreign materials such as substrates of silicon carbide (SiC), silicon, or sapphire. The atomic lattice mismatch of GaN on a foreign substrate leads to unavoidable defects in the crystal structure of the deposited GaN thin films, inevitably leading to output power degradation over the life of the LED. An almost ideal starting material would therefore be a native crystal of non-polar or semi-polar GaN. Very expensive (thousands of dollars per substrate) and small (2 inch hexagonal wafers) C-plane polar crystal faced GaN wafers have been recently produced and are commercially available. There is a pressing need to dramatically reduce the cost of this starting material and a need to convert the polar C-Plane configuration to non-polar M-plane in order to supply reasonably priced process substrates for the production of GaN-based thin film LEDs that exhibit reduced droop, high efficiency, high quality, and low cost.

Starting with a commercially available C-Plane crystalline GaN, embodiments of the present invention herein can be used to free up both non-polar and semi-polar surfaces of GaN that may be used as growth substrates for improved efficiency LEDs that minimize or significantly reduce droop. Area expansion or magnification by means of embodiments of the present invention also dramatically reduces the high materials cost. The wafer of GaN may be patterned with a series of fine micro-scale lines substantially all in one direction across the entire wafer or with several series of lines in smaller chip patterns on the wafer. In some embodiments, the lines, produced by lithographic methods well known to those skilled in the art, are aligned to the non-polar M-planes in the wafer. They may consist of dielectrics such as silicon oxides and/or nitrides and/or electric conductors such as aluminum or molybdenum. These lines should be resistant to a follow-on plasma-induced etch process; many thin film materials satisfy this condition and are known to those skilled in the art and are widely used to mask the dry etch of GaN. These lines may be produced all on one side of the wafer or, in other embodiments, are produced on both sides of the wafer, in a staggered pattern, such that a line on one side does not coincide vertically straight down with one on the other side but rather are staggered over one step so that an open area in the lines on one side coincide with a closure formed by the lines on the opposite side.

After lithographically forming the thin film lines, the GaN wafer is dry etched in a plasma such as Reactive Ion Etch (RIE) or high speed Inductively Coupled Plasma (ICP) etch. The substrate may be etched one side at-a-time or, in other embodiments, is etched both sides at-a-time to reduce processing time and additional handling. RIE and ICP etch in an anisotropic fashion result in substantially vertical sidewalls that can exhibit a high aspect ratio. A 10:1 ratio may be readily achieved. This ratio defines the extent of the area expansion of the process from the original wafer surface area to the new surface area of all the sides of the etched-out chips.

Etch of lines all on one side of the wafer would result is a complete separation of all the resulting pieces of GaN. Accordingly, the pieces would fall apart and be difficult to process any further. On the other hand, staggered, double-sided lines result in an accordion-like MCM module configuration. Either process destroys the integrity of the wafer and, by definition, it no longer exists as such. In the first case it has become a series of unsecured or frameless loose chips, which may not be desired. In the second case it is now a flexible, frameless MCM. By utilizing conductive metals for all or part of the etch mask lines the individual chips of the resulting MCM may have been electrically pre-connected in addition to being physically connected, if desired.

The resulting flexible MCM may be grasped at the ends, for example by an automated robotic clamp or hand that is specially designed for this purpose, and then stretched out to achieve a large area MCM. The M-plane is exposed, as a result, on what have now become both the top and bottom surfaces (or faces) of the chips. The original C-plane of the wafer face is now the thin edge of the chips and will not be used to produce the device. The flexible MCM may then be attached by a number of means, for example by laser tacking, to a low cost process substrate such as a large silicon or glass wafer or a number of other desirable process substrates and materials suitable for direct use in standard semiconductor manufacturing equipment.

Low cost GaN LEDs may be then produced on the substrate that exhibit high quality both from the standpoint of reduced droop and low lattice defects. It will be understood by those skilled in the art that the silicon oxides and nitrides holding together the individual chips will be unaffected by typical LED production processes. High temperature processing, where required, would however forbid the use of low melting point metals such as aluminum for pre-connections, and if metal pre-connections were desired, would require the use of high melting point metals such as the refractory metals. Thin film metal connections may readily be fabricated after the semiconductor LED process is completed.

There is an opportunity to further process the MCM before stretching it out in the case where the LED processes are suited to depositions in the deep trenches. This would allow one to concentrate the processing on a smaller area so that more product may be created in a given tool wherein a plurality of MCMs may be fitted into a tool. In many cases, LED processes such as Low Pressure Chemical Vapor Deposition (LPCVD) are not compatible with deep trench processing and the MCMs may need to be stretched in advance. When process concentration is possible however additional cost savings are enabled.

The process, as described above for GaN LEDs need only be slightly modified to enable the production of a number of other semiconductor products including, but not limited to, etching and stretching of diamond substrates for power electronics products, SiC for alternate LED processing, and gallium arsenide, silicon, or polysilicon for photovoltaic applications. Gallium indium arsenide (GaInN) on GaN crystals is a promising ultra-high efficiency photovoltaic technology that exhibits high radiation resistance but is very expensive to produce and could therefore greatly benefit by the cost reduction provided by embodiments of the present invention. In the case of photovoltaic products, concentrated processes such as diffusions are possible versus the LPCVD for LEDs. Different etchants may be required that are material specific. In the case of silicon and polysilicon, very high rate etch processes have been developed by the MEMS industry and exhibit material removal in excess of 50 microns per minute. A typical silicon wafer on the order of a few hundred microns thick may be etched in a matter of minutes resulting in high throughput production rates. The Bosch Process is one example of a high rate silicon plasma etch process. The Bosch Process configured for long cycle times created rippled sidewalls at high etch rates which can be advantageous for photovoltaic devices that usually require textured surfaces. The Bosch process surface rippling, attained via fewer rather than more etches to obtain rough rather than smooth sidewall surfaces, addresses the desire in the solar industry to post-process smooth wafer surfaces in order to increase internal scattering inside the active material and thereby improve internal absorption.

The above process may be described as a planar accordion etch-and-stretch process. A variation on this process could be achieved with what may be described as a vertical sidewall accordion process. This would be useful when utilizing round wafers, which most semiconductor substrates are, unlike the hexagonal GaN, which is an exception. Again a series of etch mask lines is made across the face of the round substrate such as a silicon wafer but in this case, only on one side of the substrate. Then photolithography is accomplished on the edges of the wafer by, for example, depositing dielectric and/or metal photoresist coatings on the sides in addition to the top surface. By spinning the wafer in a precision step-and-repeat chuck, a laser may be used to expose the photoresist on the sides in a vertical pattern that meets at the top, with the top lines oriented in a fashion that creates what is essentially a raster type pattern of lines such that every other side of a line is connected in a staggered fashion to the next line. At the top, a small area at the edge is masked in a curve to preserve a curve of the semiconductor. The dielectric is then etched on the sides and the top from one side only.

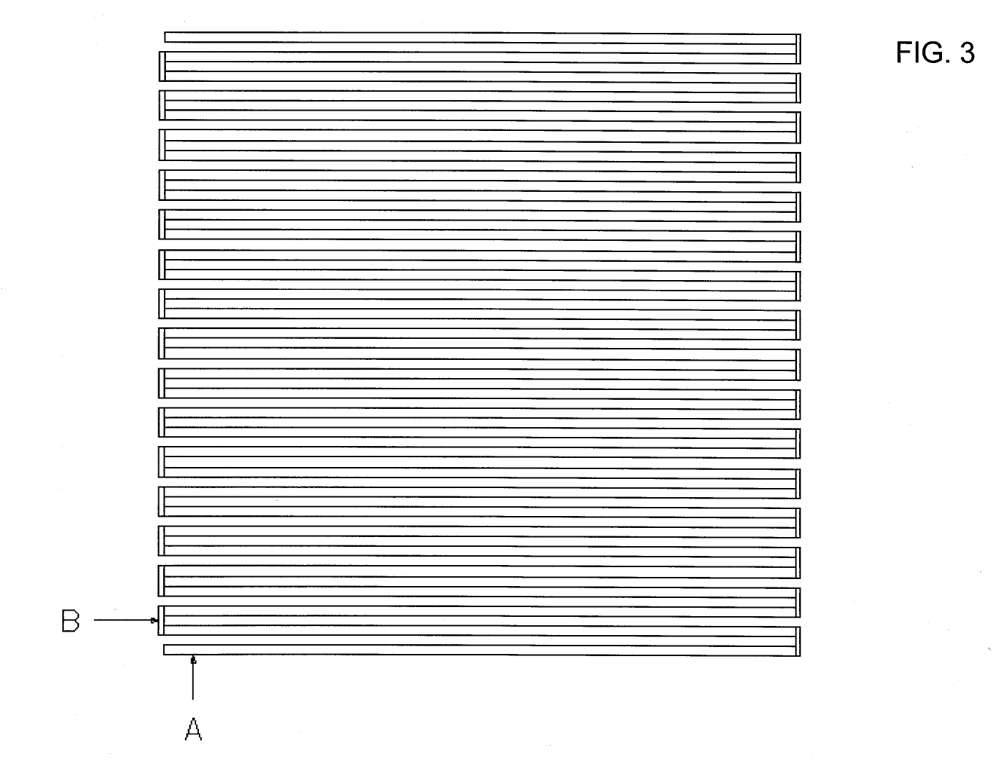

Upon etching through the wafer, a coiled up, single line of semiconductor material in a squared-off, serpentine configuration is defined. See, for example, FIG. 3, which illustrates a serpentine edge-connected vertical sidewall accordion structure according to an embodiment of the present invention. In FIG. 3, reference letter A denotes the semiconductor material and reference letter B denotes the thin film edge connection hinge. This semiconductor material is then pulled from one end with the other end pinned to achieve a single long line of semiconductor material with amplified area.

A specific crystal plane may be exposed just as with the first process with the exception of the curved corners wherein the plane rotates through a variety of crystal planes. In this case, the line of semiconductor material is contiguous and is not an MCM. This may require a very high aspect ratio at the top curve in order for the substrate to be made very thin (a few microns) in the region and therefore highly flexible at the edge. This may only be practical for thinner wafers and materials for which ultra-high aspect ratios have been achieved with plasma etch. In the case where the small area at the top, at the edge, is not masked off, then only the thin dielectrics and/or metals hold the semiconductor lines together. This is more readily achieved as the thickness of the sidewall dielectric in the range of a few microns is readily achievable but the line is now not a line of continuous semiconductor material but is rather multiple lines joined by dielectrics and/or metals. This creates an unusual line that has multiple, non-equal interruptions and which is less amenable to making a wide variety of products. It is perfectly suitable for producing wide area photovoltaic panels since when placing a large number of lines next to each other and electrically connecting them in parallel, a randomly placed bit of dielectric or conductor is unimportant. A square substrate processed in this manner would have equally spaced regular intervals of breaks in the lines and equal length lines but may require a more sophisticated edge writing lithography tool than one based on a spinning chuck. It should be apparent to one skilled in the art that a scanning laser could be readily used to write the edge of a square substrate.

Another exemplary embodiment of the invention is as follows.

Solar photovoltaics hold the promise of being a major non-polluting renewable energy source in the future but is presently not cost competitive with fossil fuels. Two major problems exist. First, the higher efficiency photovoltaic materials (e.g. gallium arsenide or gallium indium nitride) are very expensive and are generally reserved for special uses such as satellite solar applications. Second, the cost of packaging the photovoltaic materials into solar panels as well as panel installation costs are also high. Use of low cost, low efficiency photovoltaic materials such as polysilicon may require a larger number of panels than for the more sensitive photovoltaic materials, resulting in increased “balance-of-system” costs. Thus there is a need for dramatic cost reduction of high-efficiency photovoltaic solar panels. The process in the first example may be used to reduce the costs of photovoltaic materials.

Further cost reductions for photovoltaic solar substrates are possible with the following exemplary embodiment of the invention. In this embodiment, a contiguously etched spiral (or coil) of semiconductor material is unraveled like a roll of scotch tape rather than the periodically-etched series of rectangular segments that are then connected to the membrane prior to the accordion stretch in other described embodiments.

In further detail, a round wafer of semiconductor material such as gallium arsenide (GaAs) or silicon (Si) used for photovoltaic solar cells may be processed as in the first example with thin films and photoresist. The substrate may be coated on the bottom with an etch-resistant material or attached to an etch-resistant process substrate. Patterning of the substrate is performed with a low-cost lithography tool somewhat resembling a commercial DVD player wherein the substrate is rotated on a precision rotary stage and exposures made, by example, with a modulated multiple-spot ultraviolet solid-state laser head. A spiral pattern is fabricated in the thin films instead of a line pattern as before by spinning the substrate and linearly incrementing the write head across the substrate radius. The substrate is then etched from the top only. As described before for Si, a rapid etch process with rippled sidewalls may be used. GaAs etches slower but very high aspect ratios are achievable. Furthermore, process costs may be lowered by again using a low-cost tool that also eliminates a separate lithography step. A multiple head photoelectochemical etch tool, again based on a rotary stage and a fixed ultraviolet exposure head, may be utilized to perform the etching. Photoelectrochemical etching is accomplished by supplying light energy above the bandgap of a semiconductor material that activates the illuminated area and makes it susceptible to a wet etchant while the dark unilluminated areas remain inert. Combining the lithography step with the etch step reduces costs further. The result of the etch process in either case is a thin wound ribbon of semiconductor.

A stress free semiconductor material will hold its spiral shape as etched if not disturbed and may be processed with diffusions to create one long photovoltaic cell. Stresses or disturbances will distort the spiral and can create touching of the sidewalls which would block diffusions. Attachment of the etch-resistant material or process substrate prevents this. Small patterned micro or nanoscale lines of a clear material such as silicon dioxide that pass radiation and etchants may be used on the top as a stabilizer. A freestanding substrate may be preferable for processes, such as diffusion, wherein a flow of dopant gases may be desired through the substrate. A compromise is a porous process substrate or thin films with micro holes or a patterned break in connecting lines such as the aforementioned micro or nanoscale patterns. After the semiconductor processes are completed, a plurality of spirally etched photovoltaic devices may, for example, be stretched out in parallel and attached to a large panel. The line may be laser cut when the length of panel is covered and another panel moved in place and the process continued until the line is exhausted. The various lines may then be patterned and thin films deposited to create high voltage solar panels.

The low cost lithography combined with the ultra-simple methodology of area expansion requiring only the most simplistic of equipment and process concentration substantially reduces the cost of the photovoltaic devices and panel production. The multiple line, high voltage design of the module results in a high quality panel. Utilizing expensive, high efficiency photovoltaic materials such as GaAs reduces the number of panels required per kilowatt of generated solar power, thereby significantly reducing installation costs. Utilizing low cost materials reduces the cost of the photovoltaic devices themselves to an absolute minimum bringing the overall system costs down. By utilizing inexpensive lithography equipment and processes and with the ability to perform process concentration and without unusual or costly processes involved, at area expansions up to a factor of 100, the cost of solar photovoltaics will be competitive with fossil fuels. Expected improvements in the area expansion will reduce the costs further.

A further example of the invention is as follows:

A template is produced that appears like a comb in a side view with teeth that, unlike a comb, have depth on the order of the width of the comb. This may be produced, for example, by taking a quartz, sapphire, glass, metal or other substrate that is shaped like a semiconductor wafer so that it may be processed in standard semiconductor equipment used in the microelectronics industry. The substrate may indeed be a semiconductor wafer. For minimal costs, the substrate may be a molded polymeric material (plastic). The mold may be freestanding, or in other embodiments molded, by pressing a pattern into a film on a polymeric material applied to the surface of a wafer shaped substrate. A mold may be advantageous in certain embodiments since the tops and bottoms of the teeth pattern may be readily rounded in this fashion by transferring the pre-rounded shape of the mold to the polymer. Rounding helps with the stretching of the films and is discussed below. One such substrate in this example is a round quartz wafer. It will be understood by one skilled in the art that any shaped or sized substrate, such as squares and large glass panels, will suffice. However, these may require processing on less common equipment. Another desirable substrate is a stretched membrane of smooth thin film metal on a frame. This is because it is 1) directly electroplatable and 2) may be easily etched away at the end of the process by mild acid that will not affect the other thin films.

The width of the teeth shown is on a microscale such that the sum of the side areas of the teeth is much greater than the area of the face of the substrate. A first, thermally stable polymeric layer, such as, for example, hydroscopic thermally stable polyimide such as Dupont 2525, is applied to the blank substrate and cured utilizing processes well known to those skilled in the arts of the microelectronics industry. It may be preferable that the layer not be photosensitive but rather inert to the steps used in photolithography. Following this first step the teeth are then fabricated. One way of producing the teeth on standard microelectronic equipment is to use a thermally stable, high aspect ratio (20-50:1 ratio—capable of being used up to 2 mm thick) polymeric photoresist such as SU-8 (300 C no degradation, 350 C minor degradation) or photosensitive polyimide (e.g. Duramide, stable to 400 C) or other photoresist. By exposing the photoresist and developing it, high aspect ratio fins may be fabricated in the material.

The tops of the fins may be partially or fully rounded or smoothed by a number of processes including ion bombardment that creates, for example, 45 degree facets in sharp edges due to the optimum transfer of ion momentum during the bombardment in that direction. Additional photolithographic processes may be used to achieve truer rounding. SU-8 is sufficient for select thin film processes where the temperatures are kept relatively low (e.g.—one advanced process for a-Si is accomplished at 160 C wherein a number of other processes are much hotter 550-650 C and are beyond SU-8's or polyimide's thermal limitations). In other embodiments, the high aspect ratio pattern may be transferred into a more thermally stable material: electroplating through the teeth will, for instance, produce tall metal fins that are more thermally stable than polymeric materials (e.g. copper has a melting point of 1083 C) and may be used as fins to deposit other electronic materials onto). A simple means of achieving better thermal stability for follow-on hot processes is to apply a first thin film layer of, for instance, sputtered aluminum or other metal over the SU-8 and then remove the composite structure from the glass wafer while supporting the suspended thin films with a surrounding ring utilizing methods discussed below. This allows access to the backside SU-8 materials with aluminum on the front side. The SU-8 may then be removed by, for example, oxygen plasma etch. This leaves only the highly rippled aluminum structure in place resulting in a more thermally stable process substrate (Al has melting point of 660 C).

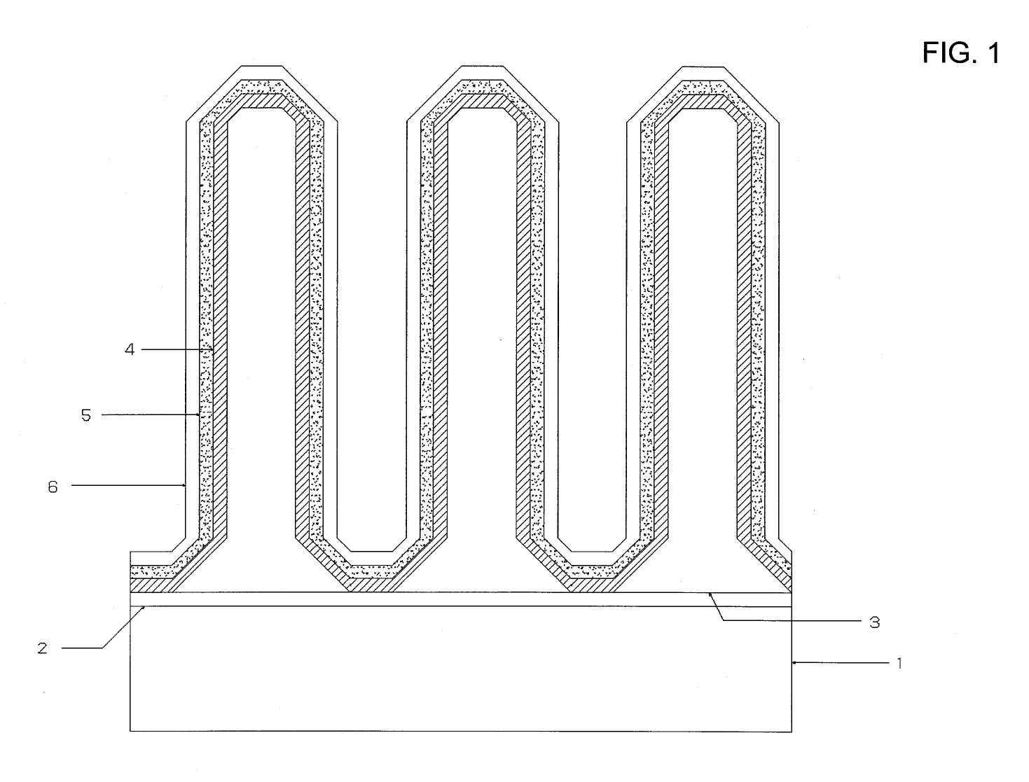

According to another embodiment, for processing convenience, the aluminum structure may be reattached to a solid substrate utilizing a more thermally stable adhesive such as a thermally reflowed glass or by laser tacking it in several places through a quartz or glass wafer. In other embodiments, the SU-8 may be stripped from the structure without freeing up the thin films from the substrate by etching small holes in the aluminum thin film at the top of the fins by, for instance, photolithography and etch or a direct laser ablation thereby creating apertures for an oxygen plasma etch. In most cases these apertures will have little effect on the efficacy of follow-on thin film processes. FIG. 1 illustrates an example of a thin film embodiment of the present invention prior to release and expansion. The substrate (1) is covered with a release layer (2). Tall SU-8 fins (3) are then covered with layers of thin film such as aluminum (4), a-Si photovoltaic layers (5) and a transparent conductor layer (6).

The fin shapes may continue all the way to the edge of the substrate. These shapes may be truncated before the edge to create any desirable stops in the pattern such as a square on an otherwise round substrate or to subdivide the larger wafer-scale pattern into a number of smaller chip-scale patterns. The underlying substrate with its polyimide layer constitutes a closed face at the bottom of the trenches. In other embodiments, a substrate may be masked and etched by a number of techniques such as deep reactive ion etch (DRIE) or photoelectrochemical etch (PECE) to create fins of the substrate material itself. However, this changes the final configuration of what constitutes the fronts and backs of the fins and is not the subject of this simple embodiment but rather of embodiments disclosed later in the present application.

To the extent that the shadowing effect of the fins does not hinder the coverage and depositions of materials, due to line-of-sight and other physical and geometrical effects, standard semiconductor industry processes such as chemical vapor deposition (CVD), plasma-enhanced CVD (PECVD), MOCVD, sputtering, electroplating or a number of others well known to those knowledgeable in the art may be used to build typical thin film devices such as a-Si or CdTe photovoltaic solar devices. In the specific cases where shadowing is problematic, such as is to be expected, for instance, with low pressure processes like metal evaporation or LPCVD, alternative processes that are insensitive to the geometry may, in some cases, be substituted to achieve similar results. The critical point here is that like the process of Everett & Blakers (U.S. Patent Application Pub. No. 2008/0223429, the entire content of which is incorporated herein by reference), c-Si photovoltaic devices are being fabricated not just on the horizontal face of a flat substrate, which is the usual industry method, but on the vertical surfaces of the fins too. Unlike Everett & Blakers, a continuous film is created that loops down into the trenches of the fins and over the tops. Note that devices such as light emitting diodes or crystalline photovoltaic cells may not be fabricated by this method since polymeric material does not have the proper surface or material characteristics to support these processes and is not sufficiently thermally stable to survive the intense heating associated with these processes. A number of polymeric materials are sufficient to withstand the more forgiving requirements of producing the amorphous thin film devices of this simple embodiment.

Upon completion of the depositions, a simple means to complete the process is to free the films from the substrate without first fixturing them. In the case where the SU-8 was left in place from the beginning this may be accomplished by the method disclosed by Jacobs in U.S. Pat. No. 6,294,407, the entire content of which is incorporated herein by reference, wherein a laser is used in conjunction with a water soak to non-destructively free the films from the substrate by destroying the adhesion of the films to the wafer. Note that only the edges of the polymer film are available to soak up water which results in long times for the film to soak up sufficient water to enable the laser liftoff. A solution to this is to rapidly and at low cost ablate small laser holes in the thin films on the tops of the fins to create apertures for the water in the entire field of the wafer. These apertures would have no detrimental effect on the final product and may in fact serve useful functions such as predrilled pathways for power connections through the film that may be fabricated after the release of the thin films.

A freestanding film is produced with extreme topography or ripple in one direction. The polymer template of the fins may then be readily removed at low cost in a batch process by oxygen plasma strip in a batch tool. Alternatively an acid strip will do the same but since some acids will also attack some thin films of interest the plasma ash may be more appropriate. The resulting film with a high degree of topography may then be mechanically stretched out (unfolded), for example, by grasping the ends and pulling the films substantially flat (for example, on an automated tool using machine vision). Pressing the thin film between a top plate and a final substrate bottom may also be used to enhance flatness. The operation is not unlike pulling the bellows of an accordion apart. More realistic means of accomplishing this would involve first adhering pulling tabs to the top surface of the film on either end for the automated tool to grasp.

It is noted that a pattern covering a round wafer with no wasted area will result in an ellipse of extreme proportions. A square pattern would result in a more usable shape after stretching but results in more waste. A compromise is to segment the pattern into smaller chip sites that may be individually pulled. This allows for filling in small chip patterns close to the rounded edges of the wafer such as is common practice in the microelectronics industry. Less waste may be achieved by patterning the largest possible square central to the round wafer and then fill in chip sites around the large square thereby producing two different pattern sizes on a wafer. It is noted that rounded edges will result in lower stresses at the points of high curvature than existed at the tops and bottoms of the fins. Applying heat during the pulling and pressure from the plates will also assist the process. It is noted that it may be preferred in some applications to not completely flatten the thin films but rather to substantially reduce the angles of the ripple. A very large increase in area may still be achieved without pressing the thin films completely flat, with less stress at the points of high curvature. Retaining a certain degree of rippling in the films will result in multiple angled surfaces that allow for multiple bounces of light rays that will enhance light absorption for certain photovoltaic technologies.

A thin film photovoltaic device that was processed substantially on a smaller substrate but was then pulled to a much larger area can be produced by the disclosed methods. 10:1 expansion factors can be readily produced and with process refinement, expansion factors up to 50:1 may be achievable. For example, SU-8 may be processed with up to 50:1 aspect ratios if exposed in multiple passes to minimize the optically induced heat build-up in the material that reduces resolution. This will enable a dramatic reduction in the cost of thin film photovoltaic panels.

Another embodiment involves the use of crystalline materials for applications such as photovoltaic solar, where higher efficiency devices are desired than are possible with thin film photovoltaic technologies, or for the production of light emitting diodes (LED) or other applications that utilize crystalline materials. The starting materials for this embodiment are typically crystalline wafers such as Si, GaAs or others for photovoltaic devices or GaAs or any typical growth substrate for LEDs such as silicon carbide (SiC) and others. It should be noted that off-the-shelf substrates are suitable for this embodiment however it may be advantageous in expanding the areas of the vertical fins 1) to have thicker substrates that yield taller fins and 2) to utilize the highest aspect ratio processes available.

As in the case of the wholly thin film embodiment, the aspect ratio may be increased with the standard planar processes only up to the point where the shadowing effect of the fins becomes detrimental. At this point, other processes may need to be utilized that are not sensitive to shadowing. In this case thicker substrates are more desirable up to the thickness that the high aspect ratio fins can be readily processed. It is usually the opposite case for processing these devices in a planar fashion on the horizontal face of the substrate and therefore it is a usual industry practice to slice and utilize the thinnest possible substrates since only a micro-thin layer of functional devices is usually made on the top of the substrate. Utilizing the thinnest possible substrates that may be readily processed is done to conserve material, much of which is wasted in sawing off many thin substrates from crystalline ingots. In the case of processing on vertical fins, the ability to use thicker substrates will significantly reduce wafer-sawing losses and further conserve expensive materials.

For a device technology wherein no, or only poor, alternative processes exist for fabrication on the sidewalls of the vertical fins that device technology may still benefit from a key aspect of this invention. In the case of very expensive substrate material such as SiC for LED production, the technology utilizes LPCVD for the fabrication of the thin film layers and is sensitive to shadowing effects. The technology may not therefore be readily produced from the standard planar depositions. The substrate material costs are however so substantial that the technology would benefit from any means to conserve material that does not introduce excessive new costs. In this case it would be beneficial to first form the fins by a number of possible high aspect ratio etch processes such that the costs to do so are not excessive.

With the basic fin shapes fabricated and prior to performing any further device fabrication processes, the vertical fins may be first stretched out by the basic accordion methods described herein and then transferred to the surface of a significantly larger, low cost process substrate such as a silicon wafer. The standard planar thin film device processes may then be accomplished in this configuration to produce the LEDs in a fashion that is highly conservative of the expensive SiC insofar as the surface area of material has been substantially expanded from its original wafer-based configuration. In this embodiment wherein no sidewall processing is to be performed, a kerfless or nearly kerfless cleaving technique would conserve the maximum amount of materials. In this case, slivers of materials are produced with no spacing and subsequent loss of materials between slivers as is the case in producing fins. These slivers may be produced by advanced lithographic-based scribe-and-break techniques or by inducing materially modified channels in the crystal with, for instance, an ion beam, that serve as a scribe lines.

According to another embodiment, for a complete sidewall process following the normal order of process steps, the first step in a crystalline embodiment may utilize a first shallow etch of the fins such as 111 crystalline plane selective KOH of silicon or other high aspect ratio etch process. This first shallow etch is stopped after a depth of only a micron or more. At this point it is useful to build up a narrow strap pattern of inert, thermally stable material that will survive and not interfere with follow-on processes such as material growths or diffusion. This material may be glass (silicon dioxide or silicon nitride) or refractory metal or other material that is thermally stable and inert to follow-on processes. This strap may be readily made by lithography and etch processes well known to those skilled in the art of microelectronics and MEMs device fabrication of planarizing the partially etched trench with a polymeric material and depositing the strap material over it and patterning it, and then using plasma etch to selectively remove the polymer leaving multiple suspended bridges of the strap material. Such bridges would not interfere with follow-on wet 111 anisotropic etch of the crystalline plane. Such bridges would interfere to an extent with DRIE as they would shadow the plasma but are feasible to a certain extent if the initial etch is deep enough.

It should be noted that these bridges are not absolutely necessary and they may be absent in other embodiments. The bridges do, however, increase stabilization of the fins against side-to-side displacement. Such displacement would partly arise from mechanical touching which is routinely avoided, in any case, in microelectronics processing. It is however impossible to avoid the drag forces of moving gases or liquids which, although they may be significantly reduced or minimized in a well-controlled process, nevertheless exist. Thermally induced motions are naturally minimized since the starting substrate is of uniform thermal expansion but may become non-uniform due to depositions and diffusions. The stabilizer straps are an added step and hinder certain processes but add mechanical stability and can be used on a case-by-case basis depending on the application. Straps may be used on the backside also but it is easier to fabricate these by simply applying a solid film first since in the case of single sided etch, the etch proceeds down to these straps.

A number of other means are available to fabricate straps if desired. An example would be to apply the pattern from a separate thin film by utilizing thin film transfer. Polymeric adhesives are disclosed in U.S. Pat. No. 5,055,907 and U.S. Pat. No. 6,294,407, the entire contents of which are incorporated herein by reference. These adhesives are not suitable for use in processes that are subject to intense heating. Inorganic adhesive methods may be employed by utilizing a reflowed glass as an adhesive or by converting a composite polymeric/inorganic material to a completing inorganic material by utilizing oxygen plasma, for instance, or thermal ashing techniques.

A top strap may be produced serially by first patterning a thin film and utilizing a first isotropic etch to undercut the thin film and then switching to an anisotropic etch. Alternatively since no process is perfectly anisotropic, one can pattern the top strap pattern narrow enough so that it becomes undercut during the main etch process. There are many techniques known to those skilled in the art of MEMs and microelectronic fabrication techniques to serially fabricate suspended top straps.

Deep etching is then commenced by a number of means that includes PECE, DRIE or crystalline plane anisotropic etch until the fins are etched fully through the substrate except at the edges, which are left intact to support the resulting fins. It is useful in some cases to partially etch the edges to create slotted guides for a fin straightening process at the end of the fabrication process, which is discussed below. Various devices are then built up on the sides of the fin, such as single junction or multi junction photovoltaic solar devices or light emitting diodes, by the processes now utilized to fabricate these devices on a planar surface. These processes are well known to those skilled in the art and may include diffusions, CVD, MOCVD, PECVD, LPCVD, passivation, texturing and others. Exotic processes such as the deposition of nanocrystalline materials on the faces may also be readily accomplished. In many cases these processes are not specific to the orientation of the semiconductor face and standard process conditions apply.

In the case of processing on the sides of fins versus the standard horizontal surface, devices are simultaneously fabricated on both faces of the fins. If this is not desirable a double etch process may be utilized wherein after building up the devices on both sides of the fin, a second deep etch is utilized to split the fins in two, resulting in twice the number of devices being fabricated and yielding a virgin surface on the new backsides of the fins. This is desirable in most cases. In other cases, it will be desirable to perform additional processes on this newly exposed face while the fins are still integrated to the substrate or afterwards when they are stretched out such as during metallization or other processes. A simple example would be electroless plating for contact metallurgy that may be performed on the backside only if the trenches of the front side are either filled or blocked.

Following the build of the devices, thin films are attached that provide for both accordion hinges and electrical connections. These may be accomplished by thin film transfer techniques previously mentioned. In other embodiments, the trenches may be filled and planarized with, for example, a temporary polymeric material and thin films may be serially fabricated over the substrate. The temporary material is then removed to yield the hinges and electrical connections.

In the case where fins are displaced out of alignment, a fine-scale mechanical straightening step may be applied. This may be readily accomplished if partially etched slotted guides were produced while etching as disclosed above. At the ends of the fins where they are robustly attached to the original substrate, no mechanical deformation is possible. Therefore, if a second more mechanically stable substrate with more shallow fins or variable height fins were aligned on one side in the partially etched trenches, it may be carefully slid in between all the high aspect ratio fins thereby straightening and realigning any displaced fins. A low friction alignment substrate is most desirable such as one with a layer of Teflon over the fins. Lubrication may also be desirable.

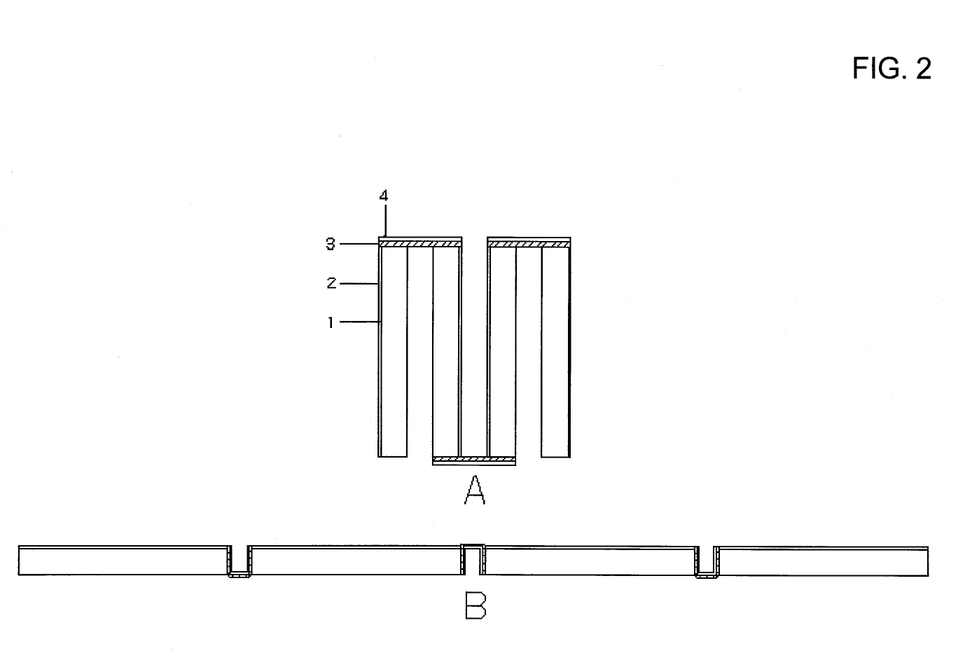

The substrate is then fixtured and edges of the fins are cut away. This may be accomplished by a number of means well known to those skilled in the art such as mechanically cutting the edges of the fins with a wafer-dicing saw or by means of a cutting laser or by patterning the edges and utilizing DRIE or other means. FIG. 2(A) illustrates a cross section of fins at this stage of completion. The crystalline fins (1) support a surface of devices (2). Thin film hinges consisting of metal (3) and polymer (4) layers are attached on the top and bottom of the fins. The substrate may now be expanded as is illustrated in FIG. 2(B) and applied to a larger substrate as the wholly thin film substrate above was. Follow-on surface structures such as plasmonic dots, nano-grids, or additional interconnects may be formed on the flattened substrates.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A contiguous thin film/semiconductor composite structure for semiconductor devices, the structure having a shape that substantially resembles bellows of an accordion, wherein upon completion of etch resistant thin film patterning on top and bottom faces of a semiconductor substrate, and semiconductor etch processes that formed said structure, the structure may be pulled or stretched out to a configuration with substantially planar surface area to achieve a significantly larger surface area than the semiconductor substrate.

2. The structure of claim 1, further comprising a deep etch of a crystalline wafer of a particular faced plane of crystalline gallium nitride (GaN) or other semiconducting crystals to reveal facets of other crystal planes or random planes to produce non-polar or semi-polar faced crystal substrates from an original polar faced substrate.

3. At least one light emitting diode (LED) made from the structure of claim 2.

4. At least one light emitting diode (LED) made from the structure of claim 1.

5. At least one photovoltaic device made from the structure of claim 1.

6. A contiguous thin film/semiconductor composite structure for semiconductor devices, the structure having a shape that substantially resembles a serpentine, wherein upon completion of etch resistant thin film patterning upon one or more edges of a semiconductor substrate, and semiconductor etch processes that formed said structure, the structure may be pulled or stretched out to achieve a substantially linear shape having a significantly larger surface area than the semiconductor substrate.

7. The structure of claim 6, further comprising a deep etch of a crystalline wafer of a particular faced plane of crystalline gallium nitride (GaN) or other semiconducting crystals to reveal facets of other crystal planes or random planes to produce non-polar or semi-polar faced crystal substrates from a polar faced substrate.

8. At least one light emitting diode (LED) made from the structure of claim 7.

9. At least one light emitting diode (LED) made from the structure of claim 6.

10. At least one photovoltaic device made from the structure of claim 6.

11. A contiguous coil of semiconductor material, the coil patterned in a substantially spiral shape with etch resistant thin film masking materials, and etched into the substantially spiral-shaped coil configured to be held at one end and pulled out at another end to achieve a substantially long and linear semiconductor substrate having a significantly larger planar surface area than the coil.

12. At least one light emitting diode (LED) made from the semiconductor substrate of claim 11.

13. At least one photovoltaic device made from the semiconductor substrate of claim 11.

14. A method comprising:
forming a semiconductor substrate substantially in an accordion shape;
etch resistant thin film patterning on top and bottom faces of the semiconductor substrate;
semiconductor etch processing the semiconductor substrate to form a contiguous thin film/semiconductor composite structure for semiconductor devices; and
pulling or stretching out the composite structure to a configuration with a substantially planar surface area to realize a significantly larger planar footprint than that of the semiconductor substrate.

15. The method of claim 14, further comprising deep etching of a crystalline wafer of a particular faced plane of crystalline gallium nitride (GaN) or other semiconducting crystals to reveal facets of other crystal planes or random planes to produce non-polar or semi-polar faced crystal substrates from an original polar faced substrate.

16. The method of claim 14, further comprising forming at least one light emitting diode (LED) from the composite structure.

17. The method of claim 14, further comprising forming at least one photovoltaic device from the composite structure.

18. A method comprising:
forming a semiconductor substrate substantially in a serpentine shape;
etch resistant thin film patterning on one or more edges of the semiconductor substrate;
semiconductor etch processing the semiconductor substrate to form a contiguous thin film/semiconductor composite structure for semiconductor devices; and
pulling or stretching out the composite structure to achieve a configuration with a substantially linear shape and having a significantly larger planar footprint than that of the semiconductor substrate.

19. The method of claim 18, further comprising deep etching of a crystalline wafer of a particular faced plane of crystalline gallium nitride (GaN) or other semiconducting crystals to reveal facets of other crystal planes or random planes to produce non-polar or semi-polar faced crystal substrates from a polar faced substrate.

20. The method of claim 18, further comprising forming at least one light emitting diode (LED) from the composite structure.

21. The method of claim 18, further comprising forming at least one photovoltaic device from the composite structure.

22. A method comprising:
patterning and etching semiconductor material using etch resistant thin film masking materials to form a substantially spiral shaped contiguous coil of the semiconductor material;
holding the coil at one end; and
pulling out the coil at another end to realize a substantially long and linear semiconductor substrate having a significantly larger planar surface area than the coil.

23. The method of claim 22, further comprising forming at least one light emitting diode (LED) from the semiconductor substrate.

24. The method of claim 22, further comprising forming at least one photovoltaic device from the semiconductor substrate.
